(19) United States
(12) Patent Application Publication
(10) Pub. No.: US 2011/0214609 A1
(43) Pub. Date: Sep. 8, 2011

(54) ATMOSPHERIC PLASMA APPARATUS

(75) Inventor: Hisashi TAKAHASHI, Kanagawa (JP)

(73) Assignee: FUJIFILM CORPORATION, Tokyo (JP)

(21) Appl. No.: 13/038,066

(22) Filed: Mar. 1, 2011

(30) Foreign Application Priority Data
Mar. 2, 2010 (JP) 2010-045402

(51) Int. Cl. C23C 16/54; C23C 16/448

(52) U.S. Cl. 118/718

(57) ABSTRACT

An atmospheric plasma apparatus for depositing a layer on a continuous base film transported in its longitudinal direction includes an electrode for treatment provided opposite to the peripheral surface of a drum electrode and upstream of an electrode for deposition in the direction of transportation of the base film, an electric power source for treatment which applies voltages to the electrode for treatment, and a reactive gas-feeding element for feeding a reactive gas for surface treatment between the drum electrode and the electrode for treatment. The atmospheric plasma apparatus as such is capable of depositing a layer without impairing effects of surface treatment, allowing a higher adhesion between the base film and the layer deposited thereon and, consequently, an efficient, successive deposition of a high-quality layer.

### BACKGROUND OF THE INVENTION

The present invention relates to atmospheric plasma apparatus for depositing a layer on a base film by utilizing atmospheric plasma.

Today, a variety of functional films (functional sheets) including gas barrier films, protective films, optical filters, and optical films such as an antireflective film are employed for various devices, such as displays, namely liquid crystal displays, organic EL displays and the like, optical elements, semiconductor devices, and thin-film solar cells.

Functional films are generally manufactured using a layer deposition (thin film formation) technique by means of coating, or vacuum deposition such as sputtering or plasma CVD. Recently, a deposition technique utilizing atmospheric plasma is also proposed.

Unlike vacuum deposition, deposition utilizing atmospheric plasma does not require switching between vacuum and atmospheric pressure and, accordingly, can be performed successively, which leads to a high productivity, and a simple apparatus structure because of the absence of vacuum units.

In the deposition utilizing atmospheric plasma, it is preferable for an efficient deposition with a high productivity to deposit a layer successively on a continuous base film.

A known deposition apparatus for performing such deposition is a so-called roll-to-roll deposition apparatus using a feed roll as a continuous base film (base film in web form) rolled up into a roll, and a rolled-up roll as the base film after deposition as rolled up. On a roll-to-roll deposition apparatus, a continuous base film is transported from the feed roll to the rolled-up roll along a path so defined as to pass through the deposition area in which the base film is subjected to deposition, and the base film as being transported is subjected to a successive deposition in a deposition chamber while the delivery of the base film from the feed roll and the roll up of the base film after deposition on the rolled-up roll are synchronized with each other.

As is known, in one such roll-to-roll deposition apparatus, a cylindrical drum and deposition means opposite to the peripheral surface of the drum, such as an electrode and a reactive gas-feeding means, are provided, and a base film is transported while wound onto the peripheral surface of the drum, and as such subjected to a successive deposition by the deposition means.

For instance, JP 2003-328125 A discloses a method of manufacturing an optical film by atmospheric plasma discharge treatment, including using an atmospheric plasma discharge treatment apparatus to cause discharge between electrodes opposite to each other, and expose a base film transported through between the opposite electrodes to a mixed gas in a plasmatic state so as to form a thin film on the base film, in which method surface treatment is carried out by a means for surface treatment provided at least one point in the manufacturing process from the feed roll of the base film (film delivering unit (unwinder)) to the rolled-up roll of the base film after deposition (film rolling-up unit (winder)).

JP 2005-194576 A discloses a thin film forming apparatus on which a discharge space is provided by applying a radio-frequency field between electrodes opposite to each other at atmospheric pressure or a pressure approximate to atmospheric pressure, a discharge gas including a deposition gas and fed into the discharge space is excited, and a thin film is formed on a base film by exposing the base film to the excited discharge gas, and which has two or more deposition treatment zones or modes to which different deposition conditions are applicable.

It is described in JP 2005-194576 A that the discharge space is defined by a drum (roll electrode) and a plurality of electrodes (rod electrodes) opposite to the drum, and a continuous base film is transported between the drum and the opposite electrodes while wound onto the drum in a contacted manner, so as to expose it to the gas in a plasmatic state to form a thin film on the base film surface.

### SUMMARY OF THE INVENTION

During the deposition of a layer on a base film, various surface treatments are generally performed before the deposition in order to improve the adhesion between the base film and a layer deposited thereon. For instance, it is described in JP 2003-328125 A as mentioned above that a means for surface treatment is provided at least one point in the manufacturing process from the feed roll to the rolled-up roll of the base film.

The means for surface treatment may be a means for conducting plasma treatment. The surface of the base film as subjected to plasma treatment is increased in roughness and activated, which leads to the improvement in adhesion between the base film and a layer deposited thereon.

If, however, the means for surface treatment and the deposition means (drum) are positioned independently of each other as is the case with JP 2003-328125 A, the base film as subjected to surface treatment will pass through several pass rollers and so forth before reaching the deposition means (drum). As a consequence, the base film with an increased surface roughness may partly drop itself off at the surface to reduce the adhesion-improving effect, or the parts of the base film as dropped off may be divided into particles and adhered to the base film or the apparatus as foreign matter.

In addition, since the effect of activating the surface of a base film by surface treatment is weakened with the lapse of time after the surface treatment, the adhesion-improving effect is more reduced as the time required to transport the base film from the means for surface treatment to the deposition means is longer. If the adhesion between the base film and a layer deposited thereon is reduced, the layer may peel off the base film at high temperatures or upon bending.

An object of the present invention is to solve the above problems with the prior art so as to provide an atmospheric plasma apparatus for depositing a layer by utilizing atmospheric plasma on a continuous base film transported in its longitudinal direction while wound onto a drum, which is capable of successively and efficiently depositing a layer of high quality, with the adhesion between the base film and the layer deposited thereon being improved, by achieving deposition with no reduction in the effect of surface treatment performed on the base film before the deposition due to pass rollers and so forth coming into contact with the base film or the lapse of time after the surface treatment.

In order to achieve the above object, according to the present invention, there is an atmospheric plasma apparatus for depositing a layer on a continuous base film transported in its longitudinal direction, including: a cylindrical drum electrode transporting the base film wound onto the electrode in a specified area of a peripheral surface thereof; an electrode for deposition provided opposite to the peripheral surface of the drum electrode; an electric power source for deposition which applies voltages to the electrode for deposition; a gaseous raw material-feeding means for feeding between the drum electrode and the electrode for deposition a gaseous raw material for the layer to be deposited; an electrode for treatment provided opposite to the peripheral surface of the drum electrode and upstream of the electrode for deposition in a direction of transportation of the base film; an electric power source for treatment which applies voltages to the electrode for treatment; and a reactive gas-feeding means for feeding a reactive gas for surface treatment between the drum electrode and the electrode for treatment.

In the atmospheric plasma apparatus according to the present invention, it is preferable that the electrode for deposition is a second drum in a cylindrical form, and the second drum also transports a continuous base film wound onto the second drum in a specified area of a peripheral surface thereof in a longitudinal direction of the film. Further, it is preferable to include a second electrode for treatment provided opposite to the peripheral surface of said second drum, and a second reactive gas-feeding means for feeding a reactive gas for surface treatment between the second electrode for treatment and the second drum.

Further, it is preferable to include a reactive gas-sucking means for sucking the reactive gas fed by said reactive gas-feeding means, wherein the reactive gas-sucking means is so arranged that said electrode for treatment may be sandwiched between said reactive gas-feeding means and the reactive gas-sucking means in the direction of transportation of said base film. Further, it is preferable to include a second reactive gas-sucking means for sucking the reactive gas fed by said second reactive gas-feeding means, wherein the second reactive gas-sucking means is so arranged that said second electrode for treatment may be sandwiched between said second reactive gas-feeding means and the second reactive gas-sucking means in a direction of transportation of said base film. Further, it is preferable to include a gaseous raw material-sucking means for sucking the gaseous raw material fed by said gaseous raw material-feeding means, wherein the gaseous raw material-sucking means is provided downstream of said gaseous raw material-feeding means in the direction of transportation of said base film.

Further, it is preferable to include a reactive gas admixture-preventing means for preventing said reactive gas from admixture between said drum electrode and said electrode for deposition. Further, it is preferable that the reactive gas admixture-preventing means is an air knife for shielding a space between said drum electrode and said electrode for deposition from gas flow. Further, it is preferable that the reactive gas admixture-preventing means is a gas feed-controlling means for making a space between said drum electrode and said electrode for deposition higher in pressure than a space between other electrodes in pair. Further, it is preferable to include a reactive gas admixture-preventing means for preventing said reactive gas from admixture between said drum electrode and said electrode for deposition, wherein said reactive gas contains a gas component absent from said gaseous raw material.

Further, it is preferable to include a gaseous raw material admixture-preventing means for preventing said gaseous raw material from admixture between said drum electrode and said electrode for treatment. Further, it is preferable that the gaseous raw material admixture-preventing means is an air knife for shielding a space between said drum electrode and said electrode for treatment from gas flow. Further, it is preferable that the gaseous raw material admixture-preventing means is a second gas feed-controlling means for making a space between said drum electrode and said electrode for treatment higher in pressure than a space between said drum electrode and said electrode for deposition.

Further, it is preferable to include a second gaseous raw material admixture-preventing means for preventing said gaseous raw material from admixture between said second drum and said second electrode for treatment. Further, it is preferable that the second gaseous raw material admixture-preventing means is an air knife for shielding a space between said second drum and said second electrode for treatment from gas flow. Further, it is preferable that the second gaseous raw material admixture-preventing means is a third gas feed-controlling means for making a space between said second drum and said second electrode for treatment higher in pressure than a space between said drum electrode and said second drum. Furthermore, it is preferable that the gaseous raw material contains all gas components present in said reactive gas.

According to the present invention, the continuous base film, which is transported in its longitudinal direction while wound onto a drum so as to deposit a layer on it by utilizing atmospheric plasma, is subjected to surface treatment before deposition on the same drum that the base film is to be subjected to deposition on. Consequently, the base film after surface treatment is able to be transported to the deposition site keeping it from contact with any pass roller or the like, and the distance from the surface treatment site to the deposition site is short, that is to say, the lapse of time between the surface treatment and the deposition is reduced, which allows a deposition with no reduction in effect of the surface treatment, leading to an efficient, successive deposition of a layer of high quality with the adhesion between the base film and a layer deposited thereon being improved.

### BRIEF DESCRIPTION OF THE DRAWINGS

FIG. 1 is a schematic diagram showing an embodiment of the atmospheric plasma apparatus of the present invention.

FIG. 2 is a schematic diagram partially showing another embodiment of the atmospheric plasma apparatus of the present invention.

FIG. 3 is a schematic diagram showing yet another embodiment of the atmospheric plasma apparatus of the present invention.

### DETAILED DESCRIPTION OF THE INVENTION

The following description is made in order to illustrate the atmospheric plasma apparatus according to the present invention based on the preferred embodiments as shown in the attached drawings.

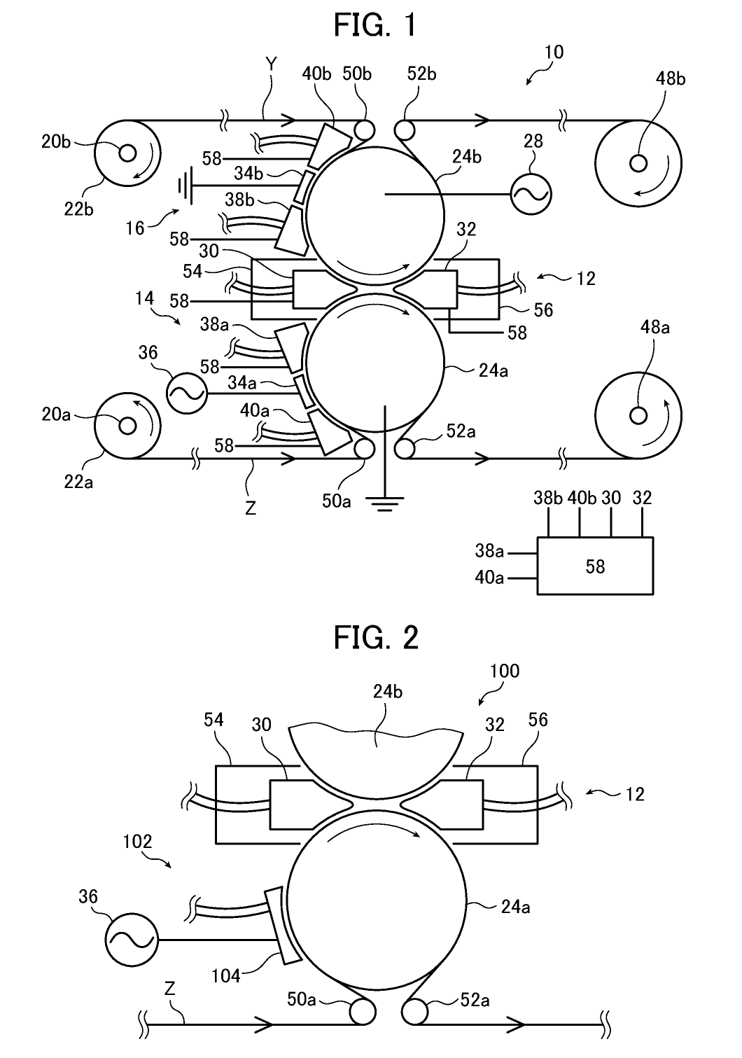

FIG. 1 schematically shows an embodiment of the atmospheric plasma apparatus of the present invention.

An atmospheric plasma apparatus 10 shown in the figure is adapted to transport a continuous base film (base film web) in its longitudinal direction, and deposit (make/form) various functional layers on the surface of the base film as being transported by atmospheric plasma CVD (atmospheric plasma-enhanced CVD) generating plasma at a pressure approximate to atmospheric pressure, so as to manufacture a functional film.

The atmospheric plasma apparatus 10 is the roll-to-roll deposition apparatus on which the continuous base film as rolled up into a base film roll is delivered from the roll, transported in its longitudinal direction, and subjected to the deposition of a functional layer during transportation, and the base film with the functional layer deposited thereon (namely, the functional film thus obtained) is rolled up.

The base film to be used in the present invention is not particularly limited, so that any object in the form of a continuous film (sheet), such as a resin film, polyethylene terephthalate (PET) film for instance, or a metallic film, is available as long as a layer is deposited on it by atmospheric plasma CVD.

The base film may also be an object in film form having the resin film as a substrate on which layers with various functions, such as a flattening layer, a protective layer, an adhesive layer, a light-reflecting layer, and an antireflective layer, are deposited.

In the case where a metallic film is used as a base film, it is necessary to form a dielectric layer on the surface of an electrode for plasma generation.

On the atmospheric plasma apparatus 10 of FIG. 1, two continuous base films Z and Y are transported while wound onto two drums, respectively, and deposition is performed on the surfaces of the base films Z and Y by generating plasma between the two drums.

The atmospheric plasma apparatus 10 has a deposition section 12, a first surface treatment section 14, a second surface treatment section 16, rotating shafts 20a and 20b, a main drum 24a, a second drum 24b, roll up shafts 48a and 48b, guide rollers 50a, 50b, 52a and 52b, and a pressure controlling means 58.

The atmospheric plasma apparatus 10 may have, apart from the shown members, a variety of members of a conventional apparatus for roll-to-roll deposition by atmospheric plasma CVD, including such members (means) as for transporting the base films Z and Y along specified paths, for instance, various sensors, transporting roller pairs, or guide members for positioning the base films Z and Y in their respective lateral directions.

The atmospheric plasma apparatus 10 transports the base films Z and Y along the paths as defined for them, respectively, feeds a gaseous raw material between the main drum 24a onto which the base film Z is wound and the second drum 24b onto which the base film Y is wound, and applies plasma exciting power between the main drum 24a and the second drum 24b to generate plasma, thus subjecting the base films Z and Y to deposition.

The base films Z and Y may be the same or different in type.

The base film Z in a rolled form, namely, a base film roll 22a is loaded on the rotating shaft 20a. The base film Y in a rolled form, namely, a base film roll 22b is loaded on the rotating shaft 20b.

With the base film roll 22a being loaded on the rotating shaft 20a, the base film Z is wound onto the main drum 24a, and caused to pass through the transportation path so defined as to extend to the roll up shaft 48a.

Similarly, with the base film roll 22b being loaded on the rotating shaft 20b, the base film Y is wound onto the second drum 24b, and caused to pass through the transportation path so defined as to extend to the roll up shaft 48b.

The transportation path for the base film Z and that for the base film Y are parallel and symmetrical to each other, and are arranged so that the main drum 24a onto which the base film Z is wound and the second drum 24b onto which the base film Y is wound may be opposite to each other.

The rotating shaft 20a is rotated by a driving source (not shown) counterclockwise in the plane of drawing so as to deliver the base film Z from the base film roll 22a, and the base film Z is then guided by the guide roller 50a along the defined path to the main drum 24a.

The rotating shaft 20b is rotated by a driving source (not shown) clockwise in the plane of drawing so as to deliver the base film Y from the base film roll 22b, and the base film Y is then guided by the guide roller 50b along the defined path to the second drum 24b.

The main drum 24a is a cylindrical member rotating about its central axis clockwise in the plane of drawing. The base film Z guided by the guide roller 50a along the defined path is wound onto the drum 24a in a specified area of the peripheral surface thereof, and transported in its longitudinal direction while held in a specified position by the drum 24a so that it may be opposite to the second drum 24b.

During the atmospheric plasma CVD for the deposition on the base film Z, the main drum 24a constitutes an electrode pair along with the second drum 24b, while, during the atmospheric plasma discharge treatment for the surface treatment of the base film Z, the main drum 24a constitutes an electrode pair along with an opposite electrode for surface treatment 34a. The main drum 24a is grounded (earthed).

The second drum 24b is a cylindrical member rotating about its central axis counterclockwise in the plane of drawing. The base film Y guided by the guide roller 50b along the defined path is wound onto the drum 24b in a specified area of the peripheral surface thereof, and transported in its longitudinal direction while held in a specified position by the drum 24b so that it may be opposite to the main drum 24a.

During the atmospheric plasma CVD for the deposition on the base film Y, the second drum 24b constitutes an electrode pair along with the main drum 24a, while, during the atmospheric plasma discharge treatment for the surface treatment of the base film Y, the second drum 24b constitutes an electrode pair along with an opposite electrode for surface treatment 34b. To the second drum 24b, an AC power source for the deposition section 12 is connected.

If necessary, the main drum 24a and the second drum 24b (hereafter also referred to collectively as “drums 24”) may also serve as a means for adjusting the temperature of a base film during deposition. In that case, certain temperature adjusting means are preferably built in the drums 24. Either of the temperature adjusting means to be built in the drums 24 is not particularly limited, so that a temperature adjusting means circulating a warming or cooling medium, a cooling means using piezoelectric elements, or any other temperature adjusting means is available.

The base films Z and Y transported while wound onto the main drum 24a and the second drum 24b, respectively, are subjected to surface treatment in the surface treatment sections 14 and 16 provided opposite to the main drum 24a and the second drum 24b, respectively, before they are subjected to deposition in the deposition section 12.

The first surface treatment section 14 conducts atmospheric plasma discharge treatment by generating plasma between the section 14 in itself and the main drum 24a to perform surface treatment on the base film Z before deposition.

Similarly, the second surface treatment section 16 conducts atmospheric plasma discharge treatment by generating plasma between the section 16 in itself and the second drum 24b to perform surface treatment on the base film Y before deposition.

The surface treatment to be conducted in the first surface treatment section 14 may be the same as, or different from, that to be conducted in the second surface treatment section 16.

The first surface treatment section 14 has the opposite electrode for surface treatment 34a, an AC power source 36, a reactive gas-feeding means 38a, and a reactive gas-sucking means 40a.

The second surface treatment section 16 has an opposite electrode for surface treatment 34b, a reactive gas-feeding means 38b, and a reactive gas-sucking means 40b.

The opposite electrode for surface treatment 34a constitutes an electrode pair along with the main drum 24a during the atmospheric plasma discharge treatment conducted in order to perform surface treatment on the base film Z before deposition.

The opposite electrode for surface treatment 34b constitutes an electrode pair along with the second drum 24b during the atmospheric plasma discharge treatment conducted in order to perform surface treatment on the base film Y before deposition.

The opposite electrodes for surface treatment 34a and 34b are known electrodes for use in plasma CVD and so forth, and are positioned opposite to the main drum 24a and the second drum 24b, respectively, and upstream of the location, at which the two drums 24 are opposite to each other, in the directions of transportation of the base films Z and Y, respectively.

The opposite electrode for surface treatment 34a of the first surface treatment section 14 is connected with the AC power source 36.

On the other hand, the opposite electrode for surface treatment 34b of the second surface treatment section 16 is grounded (earthed).

In the shown embodiment, the opposite electrodes for surface treatment 34a and 34b are each a tabular electrode, whose one face is opposite to the peripheral surface of the drum 24a or 24b.

The faces of the opposite electrodes for surface treatment 34a and 34b that are opposite to the drums 24a and 24b, respectively, are preferably made of a dielectric at their surfaces. If the opposite electrodes for surface treatment 34a and 34b have the surfaces made of a dielectric, stable plasma generation is achieved between the electrode 34a and the drum 24a, and between the electrode 34b and the drum 24b.

The reactive gas-feeding means 38a and 38b feed reactive gases for plasma generation between the main drum 24a and the opposite electrode for surface treatment 34a, and between the second drum 24b and the opposite electrode for surface treatment 34b, respectively. Any known gas feeding means for use in various plasma CVD apparatus is usable as each of the reactive gas-feeding means 38a and 38b.

The reactive gas-feeding means 38a and 38b each have a gas jet nozzle, which is located downstream of the opposite electrode for surface treatment 34a or 34b in the direction of base film transportation.

The reactive gas to be used may be selected from among known gases as appropriate to the required surface treatment. For instance, oxygen gas, nitrogen gas, hydrogen gas, helium, neon, argon, krypton, xenon, radon, water vapor, ammonia, or the like may be used alone or in combination with other such gas or gases.

The reactive gases to be fed in the first and second surface treatment sections 14 and 16 may be the same or different.

The reactive gas-sucking means 40a and 40b suck the reactive gases fed between the main drum 24a and the opposite electrode for surface treatment 34a, and between the second drum 24b and the opposite electrode for surface treatment 34b, respectively. Any known gas-sucking means (evacuation means) for use in various plasma CVD apparatus is usable as each of the reactive gas-sucking means 40a and 40b.

The reactive gas-sucking means 40a and 40b each have a suction vent, which is located upstream of the opposite electrode for surface treatment 34a or 34b in the direction of base film transportation. The reactive gas-sucking means 40a and 40b prevent reactive gases from diffusing into other regions in the apparatus.

The AC power source 36 of the first surface treatment section 14 supplies plasma exciting power to the opposite electrode for surface treatment 34a. Any known electric power source for use in various plasma CVD apparatus, such as an AC power source, a radio-frequency power source, or a pulse power source, is usable as an electric power source for supplying plasma exciting power to the opposite electrode for surface treatment 34a.

As described before, during the deposition of a layer on a base film, various surface treatments are performed before the deposition in order to improve the adhesion between the base film and a layer deposited thereon, and examples of such surface treatments include plasma discharge treatment. The surface of the base film as subjected to plasma discharge treatment is increased in roughness and activated, which leads to the improvement in adhesion between the base film and a layer deposited thereon.

If, however, the means for surface treatment and the deposition means (drum) are positioned independently of each other as is the case with JP 2003-328125 A, the base film after surface treatment will pass through several guide rollers before reaching the deposition means (drum). As a consequence, the base film with an increased surface roughness may partly drop itself off at the surface to reduce the adhesion-improving effect, or the parts of the base film as dropped off may be divided into particles and adhered to the base film or the apparatus as foreign matter. In addition, since the effect of activating the surface of a base film by surface treatment is weakened with the lapse of time after the surface treatment, the adhesion-improving effect is more reduced as the time required to transport the base film from the means for surface treatment to the deposition means is longer.

In contrast, on the inventive roll-to-roll apparatus for depositing a layer by atmospheric plasma CVD on the base film as being transported while wound onto a drum, the base film is subjected to surface treatment before deposition in such a situation that the base film is wound onto the drum on which it is to be subjected to deposition. Consequently, deposition can be performed on the base film after surface treatment keeping it from contact with any guide roller or the like. In addition, since the base film is subjected to surface treatment and deposition on one and the same drum, the distance from the surface treatment section to the deposition section is short, that is to say, the lapse of time between the surface treatment and the deposition is reduced, which allows a deposition with no reduction in effect of the surface treatment, leading to an improved adhesion between the base film and a layer deposited thereon.

The base films Z and Y as wound onto the main drum 24a and the second drum 24b and, as such, subjected to surface treatments in the surface treatment sections 14 and 16, respectively, are subjected to deposition in the deposition section 12 while kept wound onto the drums 24.

The deposition section 12 forms (deposits) a functional layer by atmospheric plasma CVD on the surface of each of the base films Z and Y, in cooperation with the main drum 24a and the second drum 24b constituting together an electrode pair.

In the shown embodiment, the deposition section 12 has an AC power source 28, a gaseous raw material-feeding means 30, a gaseous raw material-sucking means 32, and partitions 54 and 56.

The AC power source 28 supplies plasma exciting power to the second drum 24b. Any known electric power source for use in various atmospheric plasma CVD apparatus, such as an AC power source, a radio-frequency power source, or a pulse power source, is usable as an electric power source for supplying plasma exciting power to the second drum 24b.

The gaseous raw material-feeding means 30 is a known gas-feeding means for use in vacuum deposition apparatus such as plasma CVD apparatus, and introduces a gaseous raw material between the main drum 24a and the second drum 24b.

The gaseous raw material-feeding means 30 has a gas jet nozzle upstream of the location, at which the drums 24 are opposite to each other, in the direction of base film transportation.

The gaseous raw material to be used may be selected from among known gases as appropriate to the functional layer to be deposited.

If an silicon compound oxide layer is to be formed as a functional layer, for instance, it is preferable to use an inert gas, oxygen gas, and tetraethoxysilane or hexamethyl disiloxane as gaseous raw materials.

The gaseous raw material-sucking means 32 sucks the gaseous raw material as used for deposition between the main drum 24a and the second drum 24b. Any known gas-sucking means (evacuation means) for use in various plasma CVD apparatus is usable as the gaseous raw material-sucking means 32.

The gaseous raw material-sucking means 32 has a suction vent downstream of the location, at which the drums 24 are opposite to each other, in the direction of base film transportation.

The gaseous raw material-sucking means 32 prevents a gaseous raw material from diffusing into other regions in the apparatus.

In a preferred embodiment, the atmospheric plasma apparatus 10 of the present invention has the partitions 54 and 56.

The partitions 54 and 56 separate the region in which deposition is performed (deposition region) from other spaces, so as to prevent a gaseous raw material from flowing into other spaces, the regions between the surface treatment section 14 and the drum 24a and between the surface treatment section 16 and the drum 24b (surface treatment regions) in particular, and prevent reactive gases for surface treatment in the surface treatment sections 14 and 16 from flowing into the deposition region.

The partition 54 is roughly C-shaped in cross section perpendicular to the direction in which it extends, and arranged so that its roughly C-shaped inner surface may surround the gaseous raw material-feeding means 30 along with the main drum 24a and the second drum 24b. Two edges of the partition 54 corresponding to the two ends of the roughly C-shaped cross section are made as close as possible to the peripheral surfaces of the drums 24, respectively, so long as they do not come into contact with the base films.

The partition 56 is also roughly C-shaped in cross section perpendicular to the direction in which it extends, and arranged so that its roughly C-shaped inner surface may surround the gaseous raw material-sucking means 32 along with the main drum 24a and the second drum 24b. Two edges of the partition 56 corresponding to the two ends of the roughly C-shaped cross section are made as close as possible to the peripheral surfaces of the drums 24, respectively, so long as they do not come into contact with the base films.

If a gaseous raw material flows into other spaces than the deposition region, the material may accumulate/a layer may be deposited at an unwanted location on the apparatus or a base film. In the surface treatment sections 14 and 16 in particular, where surface treatment is being performed on the base films by generating plasma, a layer may be deposited on the surface of the base film under surface treatment or the surface of the opposite electrode for surface treatment 34a or 34b due to the admixture of the gaseous raw material in the surface treatment region.

Reactive gases used in the surface treatment sections 14 and 16 may also flow into the deposition region to affect the deposition.

By separating the deposition region and other spaces from each other with the partitions 54 and 56, a gaseous raw material is prevented from flowing into other spaces to accumulate at an unwanted location on the apparatus or a base film, that is to say, deposition of a layer at such a location is prevented. In addition, a reactive gas for surface treatment is prevented from flowing into the deposition region to affect the deposition.

In a preferred embodiment, the atmospheric plasma apparatus 10 of the present invention further has a pressure controlling means 58 for regulating the gas flow between the deposition region and the surface treatment regions.

The pressure controlling means 58 controls the amount of a gaseous raw material fed by the gaseous raw material-feeding means 30 and the amount of a gaseous raw material sucked by the gaseous raw material-sucking means 32, controls the amount of a reactive gas fed by the reactive gas-feeding means 38a and the amount of a reactive gas sucked by the reactive gas-sucking means 40a, as well as controls the amount of a reactive gas fed by the reactive gas-feeding means 38b and the amount of a reactive gas sucked by the reactive gas-sucking means 40b.

In other words, the pressure controlling means 58 controls the pressure in the space (deposition region) between the main drum 24a and the second drum 24b, the pressure in the space (first surface treatment region) between the main drum 24a and the opposite electrode for surface treatment 34a, and the pressure in the space (second surface treatment region) between the second drum 24b and the opposite electrode for surface treatment 34b.

The pressure controlling means 58 modifies the pressures in the deposition region and the surface treatment regions so as to regulate the gas flow between the deposition region and the surface treatment regions.

If reactive gases fed by the reactive gas-feeding means 38a and 38b are of such a type as less affecting the deposition in the deposition section 12 (gases included in gaseous raw materials, for instance), the deposition in the deposition section 12 is suitably carried out even if the reactive gases flow into the deposition region. Accordingly, nothing is required but the prevention of a gaseous raw material from flowing from the deposition region into the surface treatment regions.

A gaseous raw material in the deposition region may be prevented from flowing into the surface treatment regions by modifying the gaseous raw material feed and the reactive gas feed so that the pressures in the spaces (surface treatment regions) between the opposite electrode for surface treatment 34a and the main drum 24a and between the opposite electrode for surface treatment 34b and the second drum 24b may each be higher than the pressure in the space (deposition region) between the drum 24a and the drum 24b.

If reactive gases fed by the reactive gas-feeding means 38a and 38b are of such a type as affecting the deposition in the deposition section 12, it is preferable to prevent the reactive gases from flowing into the deposition region. The reactive gases in the surface treatment regions may be prevented from flowing into the deposition region by modifying the gaseous raw material feed and the reactive gas feed so that the pressure in the space (deposition region) between the main drum 24a and the second drum 24b may be higher than each of the pressures in the spaces (surface treatment regions) between the opposite electrode for surface treatment 34a and the drum 24a and between the opposite electrode for surface treatment 34b and the second drum 24b.

Modifying the gas feeds to regulate the gas flow between the deposition region and the surface treatment region is favorable because of a simple apparatus structure and a reduced costs.

In the case where the first surface treatment section 14 and the second surface treatment section 16 are different from each other in type of the reactive gases to be used, that is to say, reactive gases used in one of the sections 14 and 16 are all included in gaseous raw materials, while reactive gases used in the other include gases of the type not being included in gaseous raw materials, it is also possible to make the pressure in one surface treatment region higher, and the pressure in the other lower, than the pressure in the deposition region.

In the embodiment as described above, partitions and a pressure controlling means are provided in order to prevent gases from flowing from the deposition region into the surface treatment regions and vice versa, to which the present invention is not limited.

For instance, air blowing means, namely air knives, for blowing gas to the drums 24 may be provided between the deposition section 12 and the surface treatment sections 14 and 16, respectively. The air knives each blast gas to form a gas curtain having a width almost the same as the longitudinal dimension of the drums 24, so as to separate the deposition region from each surface treatment region to thereby prevent gases from flowing from the deposition region into the surface treatment regions and vice versa, that is to say, prevent a gaseous raw material in the deposition region from flowing into the surface treatment regions, and prevent reactive gases in the surface treatment regions from flowing into the deposition region.

The gas to be used for the air knives may be any gas neither affecting the deposition nor the surface treatment, with examples including air.

If the partitions 54 and 56 are used to separate the deposition region and the surface treatment regions from each other, it is necessary to keep the above-mentioned edges of the partitions from contact with the drums 24 (base films). Accordingly, gas flow may occur between the deposition region and the surface treatment regions.

In contrast, air knives used to separate the deposition region and the surface treatment regions from each other allow a more suitable prevention of the gas flow between the deposition region and the surface treatment regions.

It is also possible to use several such techniques as described above in combination for the separation of the deposition region and the surface treatment regions from each other.

In the case of a vacuum deposition apparatus having a plurality of deposition chambers and chambers for surface treatment and other treatments, individual chambers are separated from one another by partitions almost airtightly because their interiors need to be highly vacuum, so that gas in one chamber slightly flows into another chamber. Even if gas in one chamber flows into another chamber, the gas is eliminated by an evacuation means for keeping the chamber interior vacuum, or prevented from flowing into the deposition region (treatment region) by a gaseous raw material already fed in the region.

On the other hand, in a conventional atmospheric plasma apparatus, gas in one region is liable to flow into another region because deposition and surface treatment are performed at a pressure approximate to atmospheric pressure.

As described above, in a preferred embodiment of the present invention, the deposition region and the surface treatment regions are separated from each other with air knives, or by modifying the gaseous raw material feed and the reactive gas feed, so as to prevent gas in one of the deposition region and the surface treatment regions from flowing into the other.

The base films Z and Y with functional layers deposited thereon (namely, functional films obtained) are transported from the drums 24a and 24b to the guide rollers 52a and 52b, then guided by the rollers 52a and 52b to the roll up shafts 48a and 48b, respectively.

The roll up shaft 48a, as being rotated by a driving source (not shown) counterclockwise in the plane of drawing, rolls up the base film Z after deposition as guided by the guide roller 52a along the defined path into a roll. The base film Z in a rolled form is subjected to a next manufacturing step as a roll of functional film.

Similarly, the roll up shaft 48b, as being rotated by a driving source (not shown) clockwise in the plane of drawing, rolls up the base film Y after deposition as guided by the guide roller 52b along the defined path into a roll. The base film Y in a rolled form is subjected to a next manufacturing step as a roll of functional film.

On the atmospheric plasma apparatus 10, deposition is carried out as follows.

As described before, after the base film rolls 22a and 22b are loaded on the rotating shafts 20a and 20b, the base films Z and Y, as being guided by the guide rollers 50a and 50b, are wound onto the drums 24a and 24b in specified areas of their respective peripheral surfaces, then guided by the guide rollers 52a and 52b along the defined transportation paths extending to the roll up shafts 48a and 48b, respectively.

The base films Z and Y as fed from the base film rolls 22a and 22b and guided by the guide rollers 50a and 50b along the defined paths are transported along the defined transportation paths while supported/guided by the main drum 24a and the second drum 24b, respectively.

From the reactive gas-feeding means 38a and 38b, reactive gases are fed between the drum 24a and the opposite electrode for surface treatment 34a, and between the drum 24b and the opposite electrode for surface treatment 34b, respectively. At the same time, the gases present between the drum 24a and the electrode 34a, and between the drum 24b and the electrode 34b are sucked by the reactive gas-sucking means 40a and 40b, respectively.

Into the region in which the main drum 24a and the second drum 24b are opposite to each other, namely, the deposition region, a gaseous raw material is fed from the gaseous raw material-feeding means 30. At the same time, the gas in the deposition region is sucked by the gaseous raw material-sucking means 32.

When the spaces between the drum 24a and the electrode 34a and between the drum 24b and the electrode 34b have been filled with reactive gases and made stable in gas amount (pressure) by the feeding of reactive gases by the reactive gas-feeding means 38a and 38b and the suction of gases by the reactive gas-sucking means 40a and 40b, as well as the deposition region has been filled with a gaseous raw material and made stable in gas amount (pressure) by the feeding of a gaseous raw material by the gaseous raw material-feeding means 30 and the suction of gas by the gaseous raw material-sucking means 32, the opposite electrode for surface treatment 34a of the first surface treatment section 14 is supplied with plasma exciting power by the AC power source 36, and the second drum 24b is supplied with plasma exciting power by the AC power source 28.

In other words: In the deposition section 12, the main drum 24a and the second drum 24b constitute an electrode pair during atmospheric plasma CVD. In the first surface treatment section 14, the opposite electrode for surface treatment 34a and the main drum 24a constitute an electrode pair during atmospheric plasma discharge treatment. Finally, in the second surface treatment section 16, the opposite electrode for surface treatment 34b and the second drum 24b constitute an electrode pair during atmospheric plasma discharge treatment.

In the surface treatment sections 14 and 16, plasma is excited between the opposite electrode for surface treatment 34a and the main drum 24a, and between the opposite electrode for surface treatment 34b and the second drum 24b by applying plasma exciting power between the electrode 34a and the drum 24a, and between the electrode 34b and the drum 24b, so as to generate free radicals from the reactive gases, and the surfaces of the base films Z and Y transported while supported by the drums 24a and 24b are roughened and activated.

The base films Z and Y with their surfaces treated in the surface treatment sections 14 and 16 are kept wound onto the drums 24a and 24b, and transported as such to the deposition region in the deposition section 12.

In the deposition section 12, plasma is excited between the main drum 24a and the second drum 24b by applying plasma exciting power between the drum 24a and the drum 24b, so as to generate free radicals from the gaseous raw material, and a functional layer is deposited by atmospheric plasma CVD on the surface of each of the base films Z and Y transported while supported by the drums 24.

The deposition can be performed on the base films Z and Y after surface treatment keeping them from contact with any guide roller or the like because the base films are each subjected to surface treatment and deposition on one and the same drum. For the same reason, the distance from either surface treatment section 14 or 16 to the deposition section 12 is short, that is to say, the lapse of time between either surface treatment and the deposition is reduced.

The present invention is thus able to carry out deposition with no reduction in the effect of surface treatment and, consequently, achieve an efficient, successive deposition of a layer of high quality, with the adhesion between a base film and a layer deposited thereon being improved.

With respect to the structure of the surface treatment sections 14 and 16, the surface treatment section 14(16) of the atmospheric plasma apparatus 10 as shown has the opposite electrode for surface treatment 34a(34b), the reactive gas-feeding means 38a(38b) positioned downstream of the opposite electrode for surface treatment 34a(34b), and the reactive gas-sucking means 40a(40b) positioned upstream of the opposite electrode for surface treatment 34a(34b), to which the present invention is not limited. The surface treatment section 14(16) may be of such a structure as having the reactive gas-feeding means 38a(38b) positioned upstream of the electrode 34a(34b), and the reactive gas-sucking means 40a(40b) positioned downstream of the electrode 34a(34b).

If the reactive gas-feeding means 38a(38b) is positioned upstream of the opposite electrode for surface treatment 34a(34b), and the reactive gas-sucking means 40a(40b) is positioned downstream thereof, the reactive gas-sucking means 40a(40b) is adjacent to the gaseous raw material-feeding means 30 of the deposition section 12. As a consequence, the gaseous raw material fed from the gaseous raw material-feeding means 30 that happens to flow into the surface treatment section 14(16) will be sucked by the reactive gas-sucking means 40a(40b), which prevents the admixture of the gaseous raw material in the space between the opposite electrode for surface treatment 34a(34b) of the surface treatment section 14(16) and the drum 24a(24b), namely, the region in which plasma is generated in order to conduct atmospheric plasma discharge treatment.

The atmospheric plasma apparatus 10 as shown, as having the first and second surface treatment sections 14 and 16, is adapted to perform surface treatment on both the two base films Z and Y, to which the present invention is not limited. The inventive apparatus may lack the second surface treatment section 16 opposite to the second drum 24b, and be adapted to perform surface treatment on the base film Z only. In that case, the base film Y to be wound onto the second drum 24b may be replaced by a film or the like for preventing a deposition material from accumulating on the second drum 24b (electrode opposite to the main drum 24a).

It should be noted that the apparatus structure with the first and second surface treatment sections 14 and 16 is favorable in that the same deposition is performed on the two base films Z and Y.

In the atmospheric plasma apparatus 10 as shown, the surface treatment section 14(16) is composed of the opposite electrode for surface treatment 34a(34b), the reactive gas-feeding means 38a(38b), and the reactive gas-sucking means 40a(40b), to which the present invention is not limited. An opposite electrode for surface treatment integrated with a reactive gas-feeding means (gas jet nozzle) may also be used, with a reactive gas-sucking means being omitted.

FIG. 2 schematically shows part of another embodiment of the atmospheric plasma apparatus according to the present invention. In FIG. 2, an atmospheric plasma apparatus 100 is essentially identical in structure to the atmospheric plasma apparatus 10 of FIG. 1 except that the first surface treatment section 14 is replaced by a first surface treatment section 102, so that the same elements are denoted by the same reference numerals, and the following explanation is made chiefly on different elements.

The first surface treatment section 102 has an opposite electrode for surface treatment 104, and the AC power source 36.

The opposite electrode for surface treatment 104 is a showerhead electrode, which may be a known showerhead electrode for use in plasma CVD and so forth. The opposite electrode for surface treatment 104 is coupled to a reactive gas-feeding means (not shown), and connected with the AC power source 36.

In the shown embodiment, the opposite electrode for surface treatment 104 has a hollow body in a shape similar to rectangular parallelepiped, for instance, and is positioned so that its one face may be opposite to the peripheral surface of the main drum 24a. The opposite electrode for surface treatment 104 has multiple through-holes formed in its face opposite to the main drum 24a over the entire area thereof. Preferably, the face of the opposite electrode for surface treatment 104 opposite to the main drum 24a is curved along the peripheral surface of the main drum 24a.

The first surface treatment section 102 as such performs surface treatment on the base film Z as transported along the defined transportation path before the base film Z is subjected to deposition in the deposition section 12 while wound onto the main drum 24a.

To be more specific: A reactive gas is fed from the reactive gas-feeding means to the interior of the opposite electrode for surface treatment 104, and introduced between the opposite electrode for surface treatment 104 and the main drum 24a through multiple through-holes formed in the face of the electrode 104 opposite to the drum 24a.

In addition, plasma exciting power is supplied from the AC power source 36 to the opposite electrode for surface treatment 104 to excite plasma between the opposite electrode for surface treatment 104 and the main drum 24a, and surface treatment is thus performed on the base film Z.

As described above, even if the showerhead electrode, in which an opposite electrode for surface treatment and a gas jet nozzle of a reactive gas-feeding means are integrated with each other, is used, a base film before deposition can be subjected to surface treatment on the drum on which the base film is to be subjected to deposition, so that the adhesion between the base film and a layer deposited thereon is improved.

The atmospheric plasma apparatus 10 as shown is adapted to use two drums positioned opposite to each other as an electrode pair so as to perform deposition on the surfaces of two base films transported along their respective transportation paths as defined, and wound onto the drums, respectively, by introducing a gaseous raw material between the two drums and applying plasma exciting power between the drums to generate plasma, to which the present invention is not limited. The inventive apparatus may be adapted to perform deposition between a drum and a fixed electrode, with a second surface treatment section being omitted.

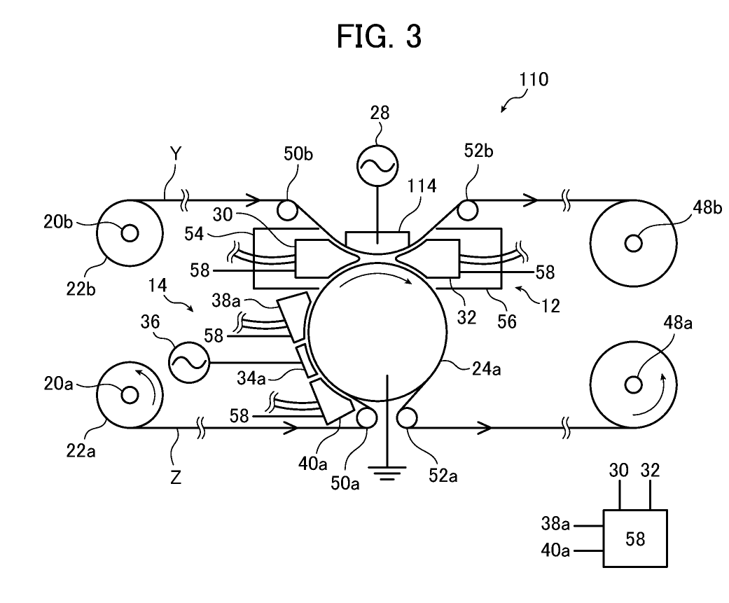

FIG. 3 schematically shows another embodiment of the atmospheric plasma apparatus of the present invention. In FIG. 3, an atmospheric plasma apparatus 110 is essentially identical in structure to the atmospheric plasma apparatus 10 of FIG. 1 except that the second drum 24b is replaced by a fixed electrode 114, and the second surface treatment section 16 is omitted, so that the same elements are denoted by the same reference numerals, and the following explanation is made chiefly on different elements.

The fixed electrode 114 constitutes an electrode pair along with the main drum 24a during the atmospheric plasma CVD for the deposition on a base film.

The fixed electrode 114 is a known electrode for use in plasma CVD and so forth, and is positioned opposite to the main drum 24a and downstream of the first surface section 14 in the direction of transportation of the base film Z.

To the fixed electrode 114, the AC power source 28 is connected.

In the shown embodiment, the fixed electrode 114 is a tabular electrode having one face opposite to the peripheral surface of the main drum 24a, with the face opposite to the main drum 24a being convexly curved.

On the atmospheric plasma apparatus 110, the base film Y as transported along the defined transportation path is wound onto the convex face of the fixed electrode 114, and, during the deposition by generating plasma between the main drum 24a and the fixed electrode 114, a layer is deposited on the surface of each of the base film Z wound onto the main drum 24a and the base film Y wound onto the fixed electrode 114.

The base film Z on the main drum 24a is subjected to surface treatment before the deposition in the first surface treatment section 14 positioned upstream of the electrode 114 in the direction of transportation of the base film Z, which improves the adhesion between the base film Z and a layer deposited thereon.

The base film Y after deposition may or may not be used as a functional film. In the latter case, a film or the like for preventing a deposition material from accumulating on the fixed electrode 114 may be used instead of the base film Y.

The atmospheric plasma apparatus according to the present invention has thus been illustrated based on the preferred embodiments, to which the present invention is in no way limited. As a matter of course, various improvements or modifications can be made without departing from the gist of the invention.

### EXAMPLES

Using the atmospheric plasma apparatus as shown in FIG. 1, a gas barrier layer was formed on a base film.

A PET film with a thickness of 100 μm and a width of 180 mm (A4300, manufactured by Toyobo Co., Ltd.) was used as a base film.

The gaseous raw materials used were nitrogen (N₂) gas as well as 5% by volume oxygen (O₂) gas and 0.1% by volume TEOS, each based on the volume of the nitrogen gas (100% by volume), which were combined with one another into a gas mixture.

The reactive gases used were nitrogen (N₂) gas and 0.1% by volume oxygen (O₂) gas based on the volume of the nitrogen gas (100% by volume), which were combined with each other into a gas mixture.

The AC power source connected to the second drum was an electric power source operating at a frequency of 150 kHz, and the AC power source connected to the opposite electrode for surface treatment was an AC power source operating at a frequency of 150 kHz.

The plasma exciting power supplied to the second drum was 2 kW, and that supplied to the opposite electrode for surface treatment was 1 kW.

During deposition, the base film temperature was adjusted to 80° C. by the temperature adjusting means built in the drums.

The thickness of the functional layer to be deposited was made to be 50 nm.

Under the conditions as above, functional films were produced with the distance from the surface treatment site to the deposition site being varied.

In Example 1, two base films were each subjected to deposition as well as surface treatment on one and the same drum. The distances from the surface treatment sites to the deposition site were 0.2 m each.

In Comparative Example 1, deposition was performed with no surface treatments in advance.

In Comparative Example 2, a base film was subjected to the surface treatment identical to that in Example 1 on a drum for treatment provided upstream of a drum for deposition before the film was subjected to deposition on the drum for deposition, on which no surface treatment was performed. The distance between the surface treatment site and the deposition site was 2.0 m.

In Comparative Example 3, surface treatment and deposition were performed in a similar manner to Comparative Example 2 except that the distance between the surface treatment site and the deposition site was 1.0 m.

In any of Comparative Examples 1, 2 and 3, conditions other than those mentioned above were the same as Example 1.

### [Adhesion]

In order to examine the produced functional films on the adhesion between the base film and the layer as deposited thereon, a cyclic bending test was initially conducted, then the adhesion was evaluated.

To be more specific: The cyclic bending test was performed at 25° C. as an IPC bending test in conformance with the IPC standard TM-650, in which a specimen is placed between a fixed plate and a movable plate so that it may be bent with its barrier face being convexed, and the movable plate is repeatedly moved. During the test, the bending radius R for the gas barrier films was 10 mm, the plate stroke was 60 mm, and the number of test cycles was 50.

Subsequently, a cross-cut test was conducted in conformance with JIS K5400 to evaluate the adhesion. In the surface of each gas barrier film having a layer deposited on its base film as described above, a right-angle lattice pattern with a 1-mm pitch was cut with a cutter knife at a 90° angle with respect to the layer surface so as to form a hundred 1-mm squares in the layer. A 2-cm wide Mylar tape [polyester tape (No. 31B) manufactured by NITTO DENKO CORPORATION] was stuck on the squares, then peeled off using a tape peeling tester. The number (n) of those squares in the layer which remained unpeeled was counted. The results are shown in Table 1 on a percentage basis.

TABLE 1

| | Adhesion |
|---|---|
| Example 1 | 100 |
| Comp. Example 1 | 50 |
| Comp. Example 2 | 75 |
| Comp. Example 3 | 80 |

As evident from Table 1 above, Example 1, in which the atmospheric plasma apparatus of the present invention was used to subject a base film to surface treatment and deposition on one and the same drum, realized an excellent adhesion between the base film and a layer deposited thereon.

In Comparative Example 1 with no surface treatments performed, the adhesion was poor. In Comparative Examples 2 and 3, in each of which a base film was subjected to surface treatment on a drum different from the drum for deposition, the adhesion between the base film and a layer deposited thereon was improved indeed as compared with Comparative Example 1, but was yet inadequate.

From the results as above, the effects of the present invention is evident.

What is claimed is:

1. An atmospheric plasma apparatus for depositing a layer on a continuous base film transported in its longitudinal direction, comprising:
a cylindrical drum electrode transporting the base film wound onto the electrode in a specified area of a peripheral surface thereof;
an electrode for deposition provided opposite to the peripheral surface of the drum electrode;
an electric power source for deposition which applies voltages to the electrode for deposition;
a gaseous raw material-feeding means for feeding between the drum electrode and the electrode for deposition a gaseous raw material for the layer to be deposited;
an electrode for treatment provided opposite to the peripheral surface of the drum electrode and upstream of the electrode for deposition in a direction of transportation of the base film;
an electric power source for treatment which applies voltages to the electrode for treatment; and
a reactive gas-feeding means for feeding a reactive gas for surface treatment between the drum electrode and the electrode for treatment.

2. The atmospheric plasma apparatus according to claim 1, wherein said electrode for deposition is a second drum in a cylindrical form, and the second drum also transports a continuous base film wound onto the second drum in a specified area of a peripheral surface thereof in a longitudinal direction of the film.

3. The atmospheric plasma apparatus according to claim 2, further comprising a second electrode for treatment provided opposite to the peripheral surface of said second drum, and a second reactive gas-feeding means for feeding a reactive gas for surface treatment between the second electrode for treatment and the second drum.

4. The atmospheric plasma apparatus according to claim 1, further comprising a reactive gas-sucking means for sucking the reactive gas fed by said reactive gas-feeding means, wherein the reactive gas-sucking means is so arranged that said electrode for treatment may be sandwiched between said reactive gas-feeding means and the reactive gas-sucking means in the direction of transportation of said base film.

5. The atmospheric plasma apparatus according to claim 3, further comprising a second reactive gas-sucking means for sucking the reactive gas fed by said second reactive gas-feeding means, wherein the second reactive gas-sucking means is so arranged that said second electrode for treatment may be sandwiched between said second reactive gas-feeding means and the second reactive gas-sucking means in a direction of transportation of said base film.

6. The atmospheric plasma apparatus according to claim 1, further comprising a gaseous raw material-sucking means for sucking the gaseous raw material fed by said gaseous raw material-feeding means, wherein the gaseous raw material-sucking means is provided downstream of said gaseous raw material-feeding means in the direction of transportation of said base film.

7. The atmospheric plasma apparatus according to claim 1, further comprising a reactive gas admixture-preventing means for preventing said reactive gas from admixture between said drum electrode and said electrode for deposition.

8. The atmospheric plasma apparatus according to claim 7, wherein said reactive gas admixture-preventing means is an air knife for shielding a space between said drum electrode and said electrode for deposition from gas flow.

9. The atmospheric plasma apparatus according to claim 7, wherein said reactive gas admixture-preventing means is a gas feed-controlling means for making a space between said drum electrode and said electrode for deposition higher in pressure than a space between other electrodes in pair.

10. The atmospheric plasma apparatus according to claim 7, wherein said reactive gas contains a gas component absent from said gaseous raw material.

11. The atmospheric plasma apparatus according to claim 1, further comprising a gaseous raw material admixture-preventing means for preventing said gaseous raw material from admixture between said drum electrode and said electrode for treatment.

12. The atmospheric plasma apparatus according to claim 11, wherein said gaseous raw material admixture-preventing means is an air knife for shielding a space between said drum electrode and said electrode for treatment from gas flow.

13. The atmospheric plasma apparatus according to claim 11, wherein said gaseous raw material admixture-preventing means is a second gas feed-controlling means for making a space between said drum electrode and said electrode for treatment higher in pressure than a space between said drum electrode and said electrode for deposition.

14. The atmospheric plasma apparatus according to claim 3, further comprising a second gaseous raw material admixture-preventing means for preventing said gaseous raw material from admixture between said second drum and said second electrode for treatment.

15. The atmospheric plasma apparatus according to claim 14, wherein said second gaseous raw material admixture-preventing means is an air knife for shielding a space between said second drum and said second electrode for treatment from gas flow.

16. The atmospheric plasma apparatus according to claim 14, wherein said second gaseous raw material admixture-preventing means is a third gas feed-controlling means for making a space between said second drum and said second electrode for treatment higher in pressure than a space between said drum electrode and said second drum.

17. The atmospheric plasma apparatus according to claim 11, wherein said gaseous raw material contains all gas components present in said reactive gas.
